(19) United States
(12) Patent Application Publication
(10) Pub. No.: US 2026/0005066 A1
(43) Pub. Date: Jan. 1, 2026

(54) METHODS FOR CONTROLLING FLATNESS OF HANDLE STRUCTURES FOR USE IN SEMICONDUCTOR-ON-INSULATOR STRUCTURES

(71) Applicant: GlobalWafers Co., Ltd., Hsinchu (TW)

(72) Inventors: Qingmin Liu, Glen Carbon, IL (US); Jeffrey L. Libbert, O'Fallon, MO (US); Guoqiang David Zhang, Ballwin, MO (US); Charles R. Lottes, Ballwin, MO (US); Xiaofei Lu, Chesterfiled, MO (US); TaeHyeong Kim, Pyeongteak (KR); Boram Bae, Chungcheongnam-do (KR); WonYong Park, ChungCheonghuk-do (KR)

(21) Appl. No.: 19/247,699

(22) Filed: Jun. 24, 2025

Related U.S. Application Data
(60) Provisional application No. 63/665,562, filed on Jun. 28, 2024.

(51) Int. Cl. H01L 21/762; C23C 16/40

(52) U.S. Cl. CPC H01L 21/76254; C23C 16/401

(57) ABSTRACT

Methods of preparing handle structures for use in semiconductor-on-insulator structures, and methods of preparing semiconductor-on-insulator structures, include forming a charge trapping layer on a front surface of a single crystal semiconductor handle substrate by depositing a semiconductor material on the front surface, where a semiconductor oxide layer is formed on the back surface and where, during deposition of the semiconductor material on the front surface, the semiconductor oxide layer limits deposition of the semiconductor material on the back surface. The semiconductor oxide layer has a sufficient thickness to withstand the deposition of the semiconductor material without exposing the back surface.

### CROSS-REFERENCE TO RELATED APPLICATIONS

This application claims the benefit of priority to U.S. Provisional Patent Application No. 63/665,562, filed Jun. 28, 2024, the disclosure of which is incorporated herein by reference in its entirety.

### FIELD

The present disclosure relates generally to the manufacture of semiconductor-on-insulator (e.g., silicon-on-insulator) structures, and more particularly, to methods of preparing handle wafers for use in semiconductor-on-insulator structures including a charge trapping layer deposited on a front surface thereof, where a backside semiconductor oxide layer is temporarily formed on a back surface of the handle wafer to prevent deposition of the charge trapping layer on the back surface of the handle wafer.

### BACKGROUND

Single crystal silicon, which is a starting material for the fabrication of semiconductor electronic devices (e.g., microelectronic devices), is commonly prepared by growing a single crystal silicon ingot by the Czochralski (“CZ”) method. In this method, polycrystalline silicon is charged to a crucible and melted, a seed crystal is brought into contact with the molten silicon, and a single crystal ingot is grown by slow extraction. Other single crystal growth techniques, such as the float zone method, may also be utilized to produce single crystal silicon ingots. The single crystal silicon ingot is trimmed and ground to have one or more flats or notches for proper crystal orientation in subsequent procedures, and is then sliced into individual single crystal silicon wafers.

Silicon wafers may be utilized in the preparation of layered silicon-insulator-semiconductor structures, also referred to as silicon-on-insulator (SOI) structures, that facilitate reducing parasitic capacitance and improving performance of the end device. An SOI structure includes a semiconductor handle wafer, a device layer, and an insulator or dielectric layer (e.g., an oxide layer) between the handle wafer and the device layer. The device layer is typically a thin layer of single crystal silicon. The semiconductor handle wafer may be made of single crystal silicon, or other suitable semiconductor materials, such as germanium, silicon carbide, silicon germanium, gallium arsenide, and other alloys of Group III and Group V elements, such as gallium nitride or indium phosphide, or alloys of Group II and Group VI elements, such as cadmium sulfide or zinc oxide.

An example process of making an SOI structure includes forming a dielectric layer (e.g., an oxide layer) on a polished front surface of a donor wafer made of single crystal silicon. Particles (e.g., hydrogen ions or a combination of hydrogen and helium ions) are implanted at a specified depth beneath the front surface of the donor wafer and form a cleave plane in the donor wafer at the specified implant depth. The front surface of the donor wafer is then bonded to a handle wafer to form a bonded structure through a hydrophilic bonding process. The donor wafer is thereafter separated (i.e., cleaved) along the cleave plane from the bonded structure to form the SOI structure. The resulting SOI structure includes a thin layer of silicon (the portion of the donor wafer remaining after cleaving) disposed atop the dielectric layer and the handle wafer. The thin layer of silicon forms the device layer of the SOI structure.

SOI structures may be implemented in radiofrequency (RF) related devices such as antenna switches and offer benefits over traditional substrates in terms of cost and integration. High resistivity handle wafers (e.g., handle wafers having a resistivity greater than 500 Ohm-cm, or greater than 1000 Ohm-cm) are frequently used in SOI structures implemented in RF devices to reduce parasitic power loss and minimize harmonic distortion inherent when using conductive substrates for high frequency applications. SOI structures that include a high resistivity handle wafer are prone to formation of high conductivity charge inversion or accumulation layers at the interface of the dielectric layer and the high resistivity handle wafer, causing generation of free carriers (electrons or holes) which reduce the effective resistivity of the handle wafer and give rise to parasitic power losses and device nonlinearity when the devices are operated at RF frequencies. These inversion/accumulation layers can be due to oxide fixed charge, oxide trapped charge, interface trapped charge, and even DC bias applied to the devices themselves.

Charge trapping layers are commonly used to improve the performance of RF devices fabricated using high resistivity SOI structures. The charge trapping layer is positioned between the high resistivity handle wafer and the dielectric layer and acts as a high defectivity layer to trap the charge in any induced inversion or accumulation layers so that the high resistivity of the handle wafer is maintained even near the surface region. Charge trapping layers may include polycrystalline or amorphous semiconductor material (e.g., polycrystalline or amorphous silicon). For example, it has been shown in academic studies that a polycrystalline silicon charge trapping layer in between the oxide layer and the handle wafer improves the device isolation, decreases transmission line losses and reduces harmonic distortions. See, for example: H. S. Gamble, et al. “Low-loss CPW lines on surface stabilized high resistivity silicon,” Microwave Guided Wave Lett., 9(10), pp. 395-397, 1999; D. Lederer, R. Lobet and J.-P. Raskin, “Enhanced high resistivity SOI wafers for RF applications,” IEEE Intl. SOI Conf., pp. 46-47, 2004; D. Lederer and J.-P. Raskin, “New substrate passivation method dedicated to high resistivity SOI wafer fabrication with increased substrate resistivity,” IEEE Electron Device Letters, vol. 26, no. 11, pp. 805-807, 2005; D. Lederer, B. Aspar, C. Laghać and J.-P. Raskin, “Performance of RF passive structures and SOI MOSFETs transferred on a passivated HR SOI substrate,” IEEE International SOI Conference, pp. 29-30, 2006; and Daniel C. Kerret al. “Identification of RF harmonic distortion on Si substrates and its reduction using a trap-rich layer”, Silicon Monolithic Integrated Circuits in RF Systems, 2008. SiRF 2008 (IEEE Topical Meeting), pp. 151-154, 2008.

In some known methods of manufacturing high resistivity SOI structures, the charge trapping layer is deposited on a front surface of the high resistivity handle wafer (e.g., using chemical vapor deposition). One problem associated with depositing the charge trapping layer is that the deposited layer may lead to unacceptable flatness of the handle wafer and, ultimately, the SOI structure. RF devices are rapidly becoming more miniaturized, and this trend continues to impose strict requirements related to acceptable SOI flatness parameters such as, for example, site backside ideal plane/range (SBIR), global backside ideal plane/range (GBIR), site frontside least squares focal plane range (SFQR), and edge site frontside least squares focal plane range (ESFQR). SOI structures having a flatness outside the requisite parameter(s) can be difficult to process on equipment with precision wafer handling automation as well as cause problems with focusing during lithography steps, among other issues. Therefore, handle wafers having a deposited charge trapping layer must have acceptable flatness. Current attempts to control the flatness of handle wafers including a deposited charge trapping layer, for example during the deposition process and/or by correction in subsequent processing (e.g., polishing), are not optimal and yield loss remains a problem.

Accordingly, there is a need for methods of preparing handle wafers including a deposited charge trapping layer in which the flatness of the handle wafer is controlled within an acceptable range.

### BRIEF SUMMARY

One aspect is a method of preparing a multilayer structure. The method includes forming a charge trapping layer on a front surface of a single crystal semiconductor handle substrate by depositing a semiconductor material on the front surface, where the single crystal semiconductor handle substrate includes the front surface, a back surface, a circumferential edge joining the front and back surfaces, where a semiconductor oxide layer is formed on the back surface and has a thickness of between 50 Angstroms to 1000 Angstroms, and where, during deposition of the semiconductor material on the front surface, the semiconductor oxide layer limits deposition of the semiconductor material on the back surface; bonding the charge trapping layer to a donor structure including a single crystal semiconductor donor substrate to thereby form a bonded structure; and removing a portion of the single crystal semiconductor donor substrate from the bonded structure to thereby transfer a single crystal semiconductor device layer onto the charge trapping layer and form the multilayer structure.

Another aspect is a method of preparing a handle structure for use in a semiconductor-on-insulator structure. The method includes forming a charge trapping layer on a front surface of a single crystal semiconductor handle substrate by depositing a semiconductor material on the front surface, where the single crystal semiconductor handle substrate includes the front surface, a back surface, a circumferential edge joining the front and back surfaces, and a semiconductor oxide layer formed on the back surface, where, during deposition of the semiconductor material on the front surface, the semiconductor oxide layer limits deposition of the semiconductor material on the back surface, and where the semiconductor oxide layer has a sufficient thickness to withstand the deposition of the semiconductor material without exposing the back surface; removing the semiconductor oxide layer from the back surface after forming the charge trapping layer on the front surface; and polishing the charge trapping layer after removing the semiconductor oxide layer to thereby prepare the handle structure.

Another aspect is a method of preparing a handle structure for use in a semiconductor-on-insulator structure. The method includes forming a semiconductor oxide layer on a back surface of a single crystal semiconductor handle substrate by depositing a semiconductor oxide material on the back surface, where the single crystal semiconductor handle substrate includes a front surface, the back surface, a circumferential edge joining the front and back surfaces, and a beveled peripheral edge extending between the circumferential edge and the back surface, where the semiconductor oxide material is also deposited on the beveled peripheral edge; removing the semiconductor oxide material from the beveled peripheral edge such that the semiconductor oxide layer is formed substantially entirely across the back surface between the beveled peripheral edge; and forming a charge trapping layer on the front surface by depositing a semiconductor material on the front surface to thereby form the handle structure, where, during deposition of the semiconductor material on the front surface, the semiconductor oxide layer limits deposition of the semiconductor material on the back surface, and where the semiconductor oxide layer has a sufficient thickness to withstand the deposition of the semiconductor material without exposing the back surface.

Advantages and features of the embodiments disclosed herein will be in part apparent and in part pointed out hereinafter.

### BRIEF DESCRIPTION OF THE DRAWINGS

FIG. 1 depicts a semiconductor-on-insulator (SOI) structure, prepared according to embodiments of the present disclosure.

FIG. 2 depicts a handle substrate used in the preparation of the SOI structure of FIG. 1, for example, according to an embodiment of a method of the present disclosure depicted in the sequence of FIGS. 3-8.

FIG. 3 depicts the handle substrate of FIG. 2, with a semiconductor oxide layer formed on a back surface thereof.

FIG. 4 depicts the handle substrate of FIG. 3, with peripheral edge portions of the semiconductor oxide layer having been removed.

FIG. 5 depicts the handle substrate of FIG. 4, with a charge trapping layer deposited on a front surface thereof to form a handle structure with the semiconductor oxide layer formed on the back surface.

FIG. 6 depicts the handle structure of FIG. 5, with the semiconductor oxide layer removed from the back surface of the handle substrate.

FIGS. 7 and 8 depict a bonding operation in which the handle structure of FIG. 6 is bonded to a front surface of a donor structure.

FIG. 9 shows probability plots of SQFR of handle structures that include a handle substrate and a charge trapping layer deposited on the handle substrate, and compares the SFQR of handle structures prepared in accordance with embodiments of the present disclosure to the SFQR of handle structures in which the charge trapping layer is deposited without using a semiconductor oxide layer on the back surface of the handle substrate.

Corresponding reference numerals are used throughout the drawings to indicate corresponding features and elements.

### DETAILED DESCRIPTION

Embodiments of the present disclosure relate to methods of preparing handle structures for use in semiconductor-on-insulator (SOI) structures. The handle structures include a single crystal semiconductor handle substrate and a charge trapping layer formed on a front surface of the handle substrate. The charge trapping layer includes semiconductor material (e.g., polycrystalline or amorphous) that acts as a high density trap region to prevent and/or kill the conductivity in the handle substrate that may otherwise occur at an interface between the handle substrate and a dielectric layer of the SOI structure. The charge trapping layer also prevents the formation of induced charge inversion or accumulation layers in the SOI structure prepared by the methods described herein that can contribute to power loss and non-linear behavior in electronic devices designed for radiofrequency (RF) device operation.

In the embodiments described herein, the charge trapping layer is deposited on a front surface of the handle substrate and a thin semiconductor oxide layer (e.g., a silicon oxide film) is formed on a back surface of the handle substrate. The semiconductor oxide layer limits or inhibits deposition of the charge trapping layer semiconductor material on the back surface of the handle substrate by preventing nucleation of semiconductor seeds (e.g., polycrystalline silicon seeds) on the semiconductor oxide material. Without being bound to a particular theory, it is believed that flatness of the handle structure including the charge trapping layer formed on the front surface thereof is deteriorated by incidental deposition of charge trapping layer semiconductor material on the back surface of the handle structure. The semiconductor material may leak between the handle substrate and a susceptor supporting the substrate in a deposition chamber (e.g., through ventilation holes of the susceptor) and subsequently deposits on the back surface facing the susceptor. The semiconductor oxide layer is used to limit or inhibit such deposition, thereby improving the flatness of the handle structure after formation of the charge trapping layer. Furthermore, the use of the semiconductor oxide layer provides an effective and cost-efficient solution to the flatness problem commonly associated with handle structures including a charge trapping layer formed on a front surface thereof. Methods of the present disclosure enable repeatedly and consistently preparing handle structures having an SFQR of less than 80 nm, or less than 60 nm, and may achieve an acceptable SFQR yield of at least 70%, at least 80%, or at least 90%.

Suitably, the semiconductor oxide layer formed on the back surface has a sufficient thickness (e.g., at least 50 Angstroms, or at least 100 Angstroms) to withstand the deposition temperatures during charge trapping layer formation without baking off the back surface. If the semiconductor oxide layer is not sufficiently thick (e.g., less than 50 Angstroms), there is a risk that the semiconductor oxide layer will bake off the back surface, either at localized regions or in its entirety, leaving the back surface at least partially exposed and susceptible for deposition of the charge trapping layer semiconductor material. Accordingly, the semiconductor oxide layer has a sufficient thickness to withstand the process conditions during formation of the charge trapping layer without exposing the back surface.

Additionally, the thickness of the semiconductor oxide layer is finely tuned, such that the semiconductor oxide layer functions as intended without being excessively thick. Excessive thickness of the semiconductor oxide layer is undesired since it requires more effort to remove after formation the charge trapping layer. In some instances, the semiconductor oxide layer is removed after formation of the charge trapping layer and prior to a subsequent polishing operation performed on the charge trapping layer, so as not to disturb the polishing operation. In this regard, the semiconductor oxide layer suitably has a thickness of between 50 Angstroms to 1000 Angstroms, between 50 Angstroms to 500 Angstroms, between 100 Angstroms to 400 Angstroms, or between 100 Angstroms to 300 Angstroms. For example, the target thickness of the semiconductor oxide layer prior to formation of the charge trapping layer is 200 Angstroms+/−100 Angstroms.

The semiconductor oxide layer can be formed using suitable oxidation techniques such as vapor phase deposition or thermal oxidation. Plasma enhanced chemical vapor deposition or atmosphere pressure chemical vapor deposition are advantageous techniques for forming the semiconductor oxide layer since these techniques are performed at a relatively low temperature (e.g., less than 450° C., such as between 100° C. to 450° C.), which reduces thermal stress induced on the handle substrate. In some instances, the handle substrate has a relatively low oxygen content (less than 9 nppma or 4.5×10¹⁷ atoms/cm³, less than 6 nppma or 3×10¹⁷ atoms/cm³, or less than 5 nppma or 2.5×10¹⁷ atoms/cm³), which makes the handle substrate susceptible to thermally induced slip. Depositing the semiconductor oxide layer at relatively low temperature using PECVD or APCVD minimizes the risk of slip in such low oxygen handle substrates.

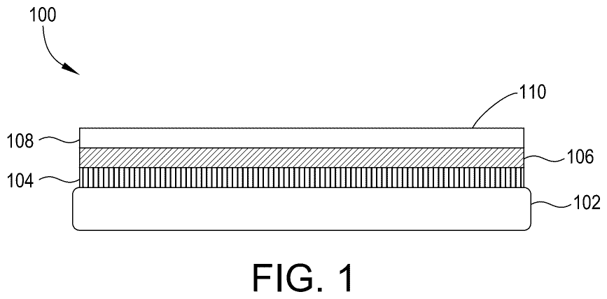

Referring now to the drawings, FIG. 1 depicts a multilayer structure 100 prepared according to embodiments of the present disclosure. The multilayer structure 100 is also referred to as a semiconductor-on-insulator structure 100 and, in some embodiments, is a silicon-on-insulator structure. The multilayer structure 100 includes, in stacked succession, a single crystal semiconductor handle substrate 102, a charge trapping layer 104, a dielectric layer 106 (also referred to as an insulating or insulator layer 106, or a buried oxide or BOX layer 106), and a device layer 108.

The handle substrate 102 is made of any suitable semiconductor material. In some embodiments, the handle substrate 102 is made of single crystal silicon. In some embodiments, the handle substrate 102 is a single crystal silicon wafer. In various embodiments, the handle substrate 102 is made of a semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

The dielectric layer 106 acts as an electrical insulator layer between the device layer 108 and the handle substrate 102 to minimize or eliminate leakage currents, lower parasitic capacitance, and otherwise improve the performance of the end device. The material used for the dielectric layer 106 varies depending on the intended application of the SOI structure 100 and/or the desired characteristics of the dielectric layer 106. In some embodiments, the dielectric layer 106 includes an oxide and/or a nitride film. In some embodiments, the dielectric layer 106 is in part or in whole a silicon dioxide (SiO₂) film. In various embodiments, the dielectric layer 106 includes a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof. In some embodiments, the dielectric layer 106 is formed of multiple dielectric layers. For example, in some embodiments, the dielectric layer 106 includes a first dielectric layer formed on the charge trapping layer 104 and a second dielectric layer bonded to the first dielectric layer, where the second dielectric layer is formed on a donor wafer from which the device layer 108 is transferred. The dielectric layer 106 has any suitable thickness to enable the dielectric layer 106 to function as described. The thickness of the dielectric layer 106 may vary depending on the intended application of the multilayer structure 100. In various embodiments, the dielectric layer 106 has a thickness between 10 nm to 10 μm, such as between 10 nm to 1 μm.

The charge trapping layer 104 is formed on the handle substrate 102 (e.g., by chemical vapor deposition) and positioned in the multilayer structure 100 between the handle substrate 102 and the dielectric layer 106. The charge trapping layer 104 includes a semiconductor material, such as a polycrystalline or amorphous semiconductor material. The semiconductor material included in the charge trapping layer 104 is suitably capable of forming a highly defective layer between the handle substrate 102 and the dielectric layer 106. In some embodiments, the charge trapping layer 104 includes polycrystalline or amorphous silicon, silicon germanium, silicon carbide, carbon-doped silicon, germanium, and combinations thereof. The term “polycrystalline” denotes a semiconductor material comprising small semiconductor crystals having random crystal orientations. For example, polycrystalline silicon grains may be as small in size as about 20 nanometers. Smaller crystal grain sizes of polycrystalline semiconductor material may provide higher defectivity in the charge trapping layer 104. The term “amorphous” denotes a semiconductor material that is in non-crystalline allotropic form, which lacks short range and long range order. Silicon grains having crystallinity over no more than about 10 nanometers may also be considered essentially amorphous silicon. The semiconductor material of the charge trapping layer 104 acts as a high density trap region to prevent and/or kill conductivity in the handle substrate 102 that may otherwise occur at an interface between the handle substrate 102 and the dielectric layer 106. The charge trapping layer 104 also prevents the formation of induced charge inversion or accumulation layers in the multilayer structure 100 that can contribute to power loss and non-linear behavior in electronic devices designed for radiofrequency (RF) device operation. The charge trapping layer 104 has any suitable thickness to enable the charge trapping layer to function as described. The thickness of the charge trapping layer 104 may vary depending on the intended application of the multilayer structure 100. In various embodiments, the charge trapping layer 104 has a thickness between 0.1 μm to 50 μm, such as between 1 μm to 10 μm.

The device layer 108 is the portion of the multilayer structure 100 upon or in which microelectronic devices are formed. In particular, the device layer 108 has an exposed or outer surface 110 that defines a top surface of the multilayer structure 100 upon or in which microelectronic devices are formed. In some embodiments, the device layer 108 includes single crystal silicon material, and the multilayer structure 100 is a silicon-on-insulator (SOI) structure having the silicon device layer 108. Thus, the multilayer structure 100 may interchangeably be referred to herein as an SOI structure 100. Although the device layer 108 is described as a silicon layer, the device layer 108 may additionally and/or alternatively include other semiconductor layers or multiple layers including, for example and without limitation, one or more layers of silicon, germanium, gallium arsenide, aluminum nitride, silicon germanium, gallium nitride, and combinations thereof. The device layer 108 has any suitable thickness to enable the device layer to function as described. The thickness of the device layer 108 may vary depending on the intended application of the multilayer structure 100. In various embodiments, the device layer 108 has a thickness between 10 nm to 3 μm, such as between 10 nm to 1 μm, or between 100 nm to 1 μm.

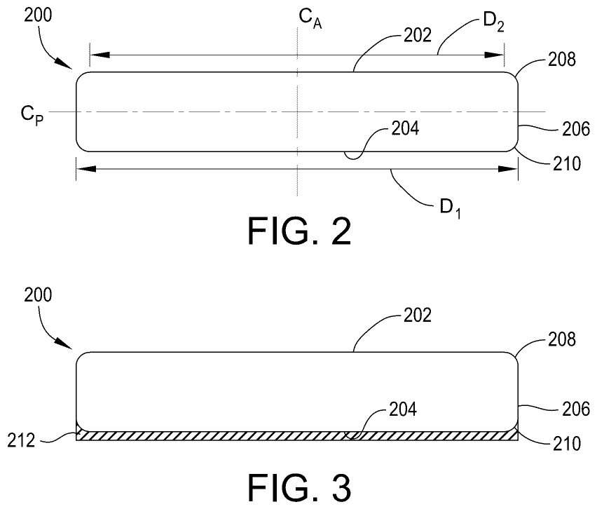

With additional reference to FIGS. 2-8, example methods of preparing the semiconductor-on-insulator structure 100 and methods of preparing a handle structure 300 for use in the semiconductor-on-insulator structure 100 will now be described.

### Preparation of Handle Structures for Use in Semiconductor-on-Insulator Structures

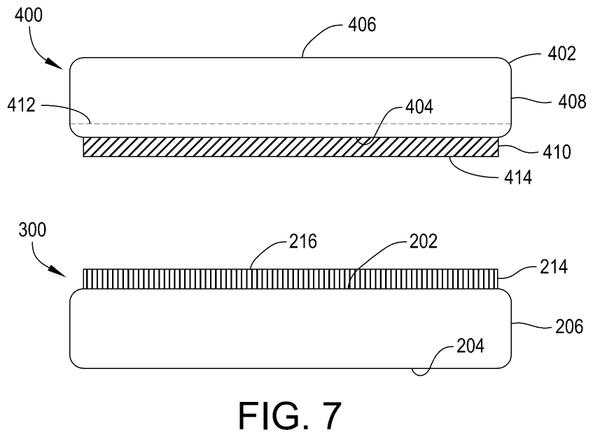

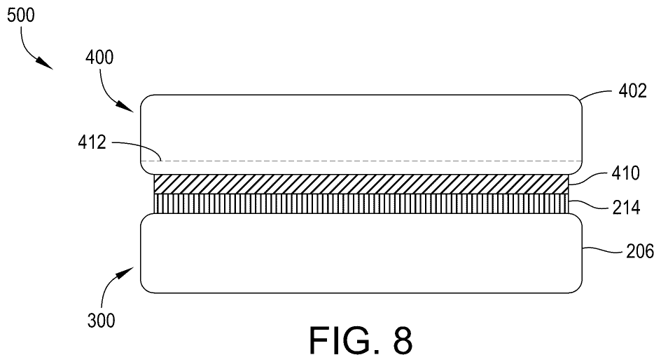

FIG. 2 depicts a single crystal semiconductor substrate 200, also referred to as a substrate 200, that is used in methods of preparing a handle structure 300 (FIGS. 5 and 6), methods of preparing a bonded structure 500 (FIG. 8), and in methods of preparing a multilayer structure 100 (FIG. 1) in accordance with embodiments of the present disclosure. In the embodiments described herein, the substrate 200 is used as a semiconductor handle substrate, e.g., a single crystal semiconductor handle wafer, for the preparation of the handle structure 300 using a process sequence described below with reference to FIGS. 2-6. The substrate 200 is also referred to as a handle substrate 200. In some embodiments, the substrate 200 is similar to, and may also be used as, a semiconductor donor substrate, e.g., a single crystal semiconductor donor wafer, used in preparing the bonded structure 500 and the multilayer structure 100 (such as a donor substrate 402 included in a donor structure 400, shown in FIGS. 7 and 8). As the description proceeds, the terms “substrate” and “wafer” are used interchangeably.

The substrate 200 includes two major, generally parallel surfaces 202, 204. One of the surfaces is a front surface 202 of the substrate 200, and the other surface is a back surface 204 of the substrate 200. The substrate 200 also includes a circumferential edge 206 joining the front surface 202 and the back surface 204. In some embodiments, the substrate 200 includes a beveled peripheral edge 208 extending between the front surface 202 and the circumferential edge 206 and/or a beveled peripheral edge 210 extending between the back surface 204 and the circumferential edge 206. The beveled peripheral edges 208, 210 are shown as being rounded in shape in the illustrated embodiment, but include other shapes in other embodiments (e.g., a chamfer). The beveled peripheral edges 208, 210 are contoured regions (e.g., rounded or chamfered) between the front and back surfaces 202, 204 of the substrate 200 and the circumferential edge 206.

The substrate 200 includes a central plane Cp between the front surface 202 and the back surface 204 and an imaginary central axis CA substantially perpendicular to the central plane Cp. A radial length of the substrate 200 is measured as the distance between the central axis CA and the circumferential edge 206. A diameter, D₁, of the substrate 200 is measured across the circumferential edge 206. The diameter D₁ varies depending on the intended application of the substrate 200. The diameter D₁ is between 150 millimeters (mm) to 450 mm in various embodiments. In some embodiments, the diameter D₁ is at least 150 mm, at least 200 mm, at least 300 mm, or at least 450 mm. In some embodiments, the diameter D₁ is about 150 mm, about 200 mm, about 300 mm, or about 450 mm. Because the surfaces 202, 204 are respectively joined to the circumferential edge 206 by the peripheral beveled edges 208, 210, a diameter, D₂, of measured across the front and back surfaces 202, 204 between the beveled edges 208, 210 is slightly less than the diameter D₂. The peripheral beveled edges 208 may extend, for example, a radial distance of between 0.1 mm to 0.5 mm. A difference between the diameters D₁ and D₂ may be, for example, between 0.2 mm to 1 mm.

Prior to any operation as described herein, the front surface 202 and the back surface 204 of the substrate 200 may be substantially identical. The surfaces 202 and 204 are referred to as a “front surface” or a “back surface,” respectively, for convenience and to distinguish the surface upon which subsequent process operations are performed. In the context of the present disclosure, the front surface 202 of the handle substrate 200 refers to the major surface of the substrate 200 that becomes an interior surface of a bonded structure 500 (FIG. 8) or a semiconductor-on-insulator structure 100 (FIG. 1). In accordance with embodiments described herein, it is upon this front surface 202 that a charge trapping layer 214 is formed (shown in FIG. 5). The back surface 204 of the handle substrate 200 refers to the major surface that is exterior to the stacked succession of layers forming the bonded structure 500 and/or semiconductor-on-insulator structure 100.

The substrate 200 includes a single crystal semiconductor material suitable for use in semiconductor-on-insulator applications. For example, in various embodiments, the substrate 200 includes a single crystal semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof. In some embodiments, the substrate 200 includes a single crystal semiconductor material selected from the group consisting of silicon, silicon carbide, silicon germanium, gallium arsenide, gallium nitride, indium phosphide, indium gallium arsenide, germanium, and combinations thereof. In certain embodiments, the substrate 200 includes single crystal silicon.

As described above, the substrate 200 has a diameter D₁ that is, for example, between 150 mm to 450 mm, such as 150 mm or at least 150 mm, 200 mm or at least 200 mm, 300 mm or at least 300 mm, or 450 mm or at least 450 mm. A thickness of the substrate 200, measured between the front and back surfaces 202, 204, varies depending on the intended application of the substrate 200. In various embodiments, the thickness of the substrate is between 250 micrometers (μm) to 1500 μm, such as between 300 μm to 1000 μm, or between 500 μm to 1000 μm. In some specific embodiments, the thickness of the handle substrate 200 is about 775 μm.

In certain embodiments, the substrate 200 is a single crystal silicon wafer which has been sliced from a single crystal ingot grown in accordance with Czochralski crystal growing methods or float zone growing methods. Such methods, as well as silicon slicing, lapping, etching, and polishing techniques for preparing wafers from the ingots, are disclosed, for example, in F. Shimura, Semiconductor Silicon Crystal Technology, Academic Press, 1989, and Silicon Chemical Etching, (J. Grabmaier ed.) Springer-Verlag, N.Y., 1982, the entire disclosure of which is incorporated by reference herein. Suitably, the wafers are polished and cleaned by methods known to those skilled in the art. See, for example, W. C. O'Mara et al., Handbook of Semiconductor Silicon Technology, Noyes Publications.

The substrate 200 has interstitial oxygen in any suitable concentration that is generally achieved by the CZ or float zone growing methods. For example, the handle substrate may have an interstitial oxygen concentration of between 1×10¹⁶ atoms/cm³ to 5×10¹⁸ atoms/cm³. Interstitial oxygen concentration may be measured according to SEMI MF 1188-1105. The interstitial oxygen concentration of the substrate 200 may be relatively low in some embodiments. For example, in some embodiments, the substrate 200 has an interstitial oxygen concentration of less than 9 nppma (4.5×10¹⁷ atoms/cm³), less than 6 nppma (3×10¹⁷ atoms/cm³), or less than 5 nppma (2.5×10¹⁷ atoms/cm³). In various embodiments, the substrate 200 has an interstitial oxygen concentration between 1×10¹⁷ atoms/cm³ to 4.5×10¹⁷ atoms/cm³, such as between 1×10¹⁷ atoms/cm³ to 3×10¹⁷ atoms/cm³, or between 1×10¹⁷ atoms/cm³ to 2.5×10¹⁷ atoms/cm³.

The substrate 200 has any resistivity obtainable by the CZ or float zone methods. The resistivity of the substrate 200 may vary based on the requirements of the end use/application of the semiconductor-on-insulator structure 100. The resistivity may vary from milliohm or less to megaohm or more. “High resistivity” substrates 200 have a minimum bulk resistivity of at least 500 Ohm-cm, such as between 500 Ohm-cm to 100,000 Ohm-cm. “Low resistivity” substrates 200 have a minimum bulk resistivity of below (less than or equal to) 500 Ohm-cm, such as between 1 Ohm-cm to 100 Ohm-cm. Methods for preparing wafers of varying resistivities are known in the art, and wafers having a desired resistivity may be obtained from commercial suppliers, such as GlobalWafers Co., Ltd., Taiwan.

In some embodiments, the substrate 200 has a relatively high minimum bulk resistivity. High resistivity single crystal semiconductor substrates 200 are generally sliced from single crystal ingots grown by the Czochralski method or float zone method, and may be subjected to a thermal anneal at a temperature ranging from 600° C. to 1000° C. in order to annihilate thermal donors caused by oxygen that are incorporated during crystal growth. In some embodiments, the substrate 200 has a minimum bulk resistivity of at least 500 Ohm-cm, at least 1000 Ohm-cm, or at least 3000 Ohm-cm, such as between 500 Ohm-cm and 100,000 Ohm-cm, between 500 Ohm-cm and 50,000 Ohm-cm, between 500 Ohm-cm and 10,000 Ohm-cm, between 1000 Ohm-cm and 50,000 Ohm-cm, between 1000 Ohm-cm and 20,000 Ohm-cm, between 1000 Ohm-cm and 10,000 Ohm-cm, between 1000 Ohm-cm and 5000 Ohm-cm, between 3000 Ohm-cm and 50,000 Ohm-cm, between 3000 Ohm-cm and 20,000 Ohm-cm, between 3000 Ohm-cm and 10,000 Ohm-cm, between 3000 Ohm-cm and 5000 Ohm-cm, between 5000 Ohm-cm and 50,000 Ohm-cm, between 5000 Ohm-cm and 20,000 Ohm-cm, or between 5000 Ohm-cm and 10,000 Ohm-cm. Methods for preparing high resistivity wafers are known in the art, and such high resistivity wafers may be obtained from commercial suppliers, such as GlobalWafers Co., Ltd., Taiwan.

In some embodiments, the substrate 200 includes a p-type or an n-type dopant. Suitable p-type dopants include boron, gallium, or combinations thereof. Suitable n-type dopants include phosphorus, antimony, arsenic, or combinations thereof. The dopant concentration in the substrate 200 may be selected based on the desired resistivity of the handle substrate. In some embodiments, the substrate 200 is undoped.

In some embodiments, prior to subsequent operations for preparing the handle structure 300, the handle substrate 200 is subjected to a double side polishing operation (DPOL) to planarize and remove surface defects from the front and back surfaces 202, 204 and/or an edge polish operation (EPOL) to smooth and remove defects from the peripheral edge. The DPOL is performed on the substrate 200 to polish the front and back surfaces 202, 204 simultaneously, improving flatness and parallelism of both surfaces. Methods and apparatus for DPOL and EPOL are known in the art, including those described, for example, in U.S. Pat. No. 5,422,316, issued Jun. 6, 1995; U.S. Pat. No. 6,189,546, issued Feb. 20, 2001; U.S. Pat. No. 6,376,335, issued Apr. 23, 2002; U.S. Pat. No. 7,008,308, issued Mar. 7, 2006; U.S. Pat. No. 7,559,825, issued Jul. 14, 2009; U.S. Pat. No. 8,192,822, issued Jun. 5, 2012; and U.S. Pat. No. 8,309,464, issued Nov. 13, 2012, the disclosures of each of which are incorporated by reference. DPOL generally involves the use of frontside and backside polishing pads that are rotated relative to the substrate 200 and work a polishing slurry against the front and back surfaces 202, 204 to remove material from the surfaces 202, 204, resulting in a flatter and/or smoother surface. EPOL generally involves polishing the wafer edges, including the circumferential edge 206, the beveled edges 208, 210, and any orientation notch or flat, by pressing an edge polishing pad or other surface against the wafer edge and working a polishing slurry against the wafer edge using the edge polishing pad. Generally, the DPOL and EPOL operations are carried out at separate stations. Suitable slurries for that may be used alone or in combination in the DPOL and/or EPOL process include a first polishing slurry comprising an amount of silica particles, a second polishing slurry that is alkaline (i.e., caustic) and typically does not contain silica particles, and/or a third polishing slurry that is deionized water. Following the DPOL and/or EPOL, the front and back surfaces 202, 204 and the beveled peripheral edges 208, 210 are sufficiently smooth for further processing to prepare the handle structure 300.

With reference to FIG. 3, in accordance with the embodiments of the present disclosure, a semiconductor oxide layer 212 is formed on the back surface 204 of the substrate 200. The semiconductor oxide layer 212 is formed on the back surface 204 prior to forming the charge trapping layer 214 on the front surface 202 of the substrate 200. The semiconductor oxide layer 212 operates to limit or inhibit the charge trapping layer 214 from forming on the back surface 204, thereby improving flatness of the handle structure 300. In various embodiments, the semiconductor oxide layer 212 includes silicon oxide material, such as silicon dioxide or silicon oxynitride. In certain embodiments the semiconductor oxide layer 212 is a silicon dioxide layer.

The semiconductor oxide layer 212 has a sufficient thickness to withstand the process conditions during formation of the charge trapping layer 214 without exposing the back surface 204, described in more detail below. Alternatively stated, the semiconductor oxide layer 212 has a sufficient thickness prior to forming the charge trapping layer 214 such that, when forming the charge trapping layer 214, the thickness of any portion of the semiconductor oxide layer 212 is not reduced to a point where a portion the back surface 204 becomes exposed to allow the charge trapping layer 214 to form on the back surface 204. In various embodiments, prior to formation of the charge trapping layer 214, the semiconductor oxide layer 212 has a thickness of at least 50 Angstroms, or at least 100 Angstroms. In some embodiments, the semiconductor oxide layer 212 is removed (e.g., by wet etching) after forming the charge trapping layer 214 and prior to subsequent operations performed on the handle structure 300 (e.g., prior to a polishing operation performed on the charge trapping layer 214). In this regard, in various embodiments, the thickness of the semiconductor oxide layer 212 is selected to withstand the process conditions during formation of the charge trapping layer 214 and to allow efficient removal of the semiconductor oxide layer 212 without excessive effort. For example, in various embodiments, the thickness of the semiconductor oxide layer 212 prior to formation of the charge trapping layer 214 is between 50 Angstroms to 1000 Angstroms, such as between 50 Angstroms to 500 Angstroms, between 100 Angstroms to 400 Angstroms, or between 100 Angstroms to 300 Angstroms. In certain embodiments, a target thickness of the semiconductor oxide layer 212 prior to formation of the charge trapping layer 214 is 200 Angstroms+/−100 Angstroms.

In embodiments of the present disclosure, the semiconductor oxide layer 212 is formed on the back surface 204 of the substrate 200 by depositing semiconductor oxide (e.g., silicon oxide) material on the front surface 202 using a vapor phase deposition method (e.g., physical vapor deposition, PVD, or chemical vapor deposition, CVD). Suitable CVD methods for depositing the semiconductor oxide layer 212 include plasma enhanced chemical vapor deposition (PECVD), atmosphere pressure chemical vapor deposition (APCVD), and low pressure chemical vapor deposition (LPCVD). For example, APCVD or PECVD is suitably used to deposit the semiconductor oxide layer 212 since it is performed at a relatively low temperature, which minimizes thermal stress on the substrate 202. Suitable apparatus for depositing the semiconductor oxide layer 212 using PECVD include the Challenger HT Series available from Technology Engine of Science (TES) or a PECVD tool available from Applied Materials. The process conditions for APCVD or PECVD to deposit the semiconductor oxide layer 212 include a temperature less than 450° C., such as between 100° C. to 450° C., or between 300° C. to 450° C. In some embodiments, the semiconductor oxide layer is deposited using PECVD performed at a temperature of about 400° C. As described above, the handle substrate 200 may have a relatively low oxygen concentration, such as between 1×10¹⁷ atoms/cm³ to 4.5×10¹⁷ atoms/cm³, between 1×10¹⁷ atoms/cm³ to 3×10¹⁷ atoms/cm³, or between 1×10¹⁷ atoms/cm³ to 2.5×10¹⁷ atoms/cm³. Low oxygen concentrations in the substrate 200 may create the risk of thermally induced slip in high temperature processes, such as high temperature oxide deposition or other oxidation processes (e.g., thermal oxidation). Depositing the semiconductor oxide layer 212 using low temperature PECVD or APCVD minimizes the risk of slip defects in the substrate 200 having such low oxygen concentrations.

As described above, the semiconductor oxide layer 212 includes silicon oxide in some embodiments. In these embodiments, the silicon oxide material is deposited (e.g., using PECVD or APCVD) on the back surface 204 of the substrate 200 in an atmosphere containing an oxygen-containing precursor and a silicon-containing precursor. Suitable oxygen-containing precursors for depositing the silicon oxide material include nitrous oxide (N₂O), oxygen (O₂), or ozone gas. Suitable silicon precursors depositing the silicon oxide material include methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), among others. In certain embodiments, the silicon oxide material is deposited in an atmosphere containing nitrous oxide and silane. In some embodiments, the silicon oxide material is deposited in the atmosphere containing the oxygen-containing precursor, the silicon-containing precursor, and a carrier gas. The carrier gas is helium is some embodiments.

Alternative techniques other than vapor phase deposition can also be used to form the semiconductor oxide layer 212 on the back surface 204 of the substrate 200. For example, in some embodiments, the semiconductor oxide layer 212 is formed using thermal oxidation. Suitable apparatus for thermally oxidizing the handle substrate 200 include a furnace such as an ASM A400 or an ASM A412. The temperature ranges from 750° C. to 1200° C. in an oxidizing ambient. Thermal oxidation is performed at a higher temperature than PECVD or APCVD, which may create a higher risk of damaging to the substrate 200 due to thermal stresses. However, the semiconductor oxide layer 212 has a relatively small thickness (e.g., between 50 Angstroms to 1000 Angstroms as described above), which can be achieved at relatively short thermal oxidation durations, limiting the thermal stress induced on the substrate 200. In embodiments where the substrate 200 includes single crystal silicon, thermal oxidation is suitably used to form a silicon oxide layer as the semiconductor oxide layer 212. The oxidizing ambient atmosphere for thermal oxidation includes O₂, or a mixture of oxygen, O₂, and inert gas, such as Ar or N₂. In some embodiments, the oxidizing ambient atmosphere may include O₂ and a nitrogen-precursor (e.g., ammonia), which is suitable for forming a silicon oxynitride layer as the semiconductor oxide layer 212. In various embodiments, the oxygen content of the oxidizing ambient atmosphere varies from 1 to 10% by volume (v/v) O₂, or higher than 10% v/v O₂. “Dry oxidation” is accomplished in an oxidizing ambient atmosphere that includes up to 100% O₂ to grow the semiconductor oxide layer 212 (e.g., silicon oxide). “Wet oxidation” is accomplished in an oxidizing ambient atmosphere that includes a mixture of inert gas, such as Ar or N₂, and oxidizing gases, such as O₂ and water vapor. Dry oxidation or wet oxidation can also be used to form a semiconductor oxynitride material (e.g., silicon oxynitride) as the semiconductor oxide layer 212, and, in such instances, the dry or wet oxidizing atmosphere also includes a nitriding gas (e.g., ammonia). To perform the thermal oxidation process, the substrate 200 is loaded into the suitable apparatus (e.g., an ASM A400 or an ASM A412 furnace), the temperature is ramped to the oxidizing temperature in the oxidizing atmosphere. In wet oxidation applications, water vapor is introduced into the gas flow at a desired temperature. After a thickness of the semiconductor oxide layer 200 has been obtained, the oxidizing gas flow is terminated, the furnace temperature is reduced, and the substrate 200 is unloaded from the furnace.

As described above and below, the thickness of the semiconductor oxide layer 212 formed (e.g., by PECVD, APCVD, or thermal oxidation) on the back surface 204 is sufficient to withstand the process conditions during formation of the charge trapping layer 214 without exposing the back surface 204. For example, the thickness of the semiconductor oxide layer 212 prior to formation of the charge trapping layer 214 is between 50 Angstroms to 1000 Angstroms, such as between 50 Angstroms to 500 Angstroms, between 100 Angstroms to 400 Angstroms, or between 100 Angstroms to 300 Angstroms, or a target thickness of the semiconductor oxide layer 212 prior to formation of the charge trapping layer 214 is 200 Angstroms+/−100 Angstroms. After forming the semiconductor oxide layer 212 is formed on the back surface 204, the handle substrate 200 is subjected to edge etching, polishing, and/or cleaning operations before forming the charge trapping layer 214 on the front surface 202. During these operations, the thickness of the semiconductor oxide layer 212 may be reduced. To compensate for the reduction in thickness experienced by the semiconductor oxide layer 212 during the intermediate etching, polishing, and/or cleaning operations, the thickness of the semiconductor oxide layer 212 when formed on the back surface 204, e.g., after PECVD, APCVD, or thermal oxidation, may be above the targeted thickness of the semiconductor oxide layer 212 prior to forming the charge trapping layer 214.

Still referring to FIG. 3, the semiconductor oxide layer 212 formed on the back surface 204 of the substrate 200 (e.g., by PECVD, APCVD, or thermal oxidation) may also be formed on the beveled peripheral edge 210 between the back surface 204 and the circumferential edge 206. Although not shown in FIG. 3, the semiconductor oxide layer 212 may also form on the circumferential edge 206 and/or the beveled peripheral edge 208 between the front surface 202 and the circumferential edge 206. Additionally, particularly in embodiments where thermal oxidation is used to form the semiconductor oxide layer 212, a semiconductor oxide layer may also form on the front surface 202 of the substrate 200. The semiconductor oxide layer 212 is not desired in regions of the substrate other than the back surface 204 (e.g., the front surface 202, the beveled peripheral edges 208, 210, and the circumferential edge 206). Semiconductor oxide material deposited on the front surface 202 may prevent adequate deposition of the charge trapping layer 214 on the front surface. Semiconductor oxide material could also contribute to unacceptable flatness characteristics (e.g., SFQR) of the substrate 200, and, thus, the handle structure 300. Moreover, in some embodiments the semiconductor oxide layer 212 on the back surface 204 is removed from the handle structure 300 after forming the charge trapping layer 214, and it is difficult to remove the semiconductor oxide layer from regions of the substrate 200 that are in proximity to the charge trapping layer 214 once formed (e.g., the beveled peripheral edges 208, 210) without damaging the charge trapping layer 214.

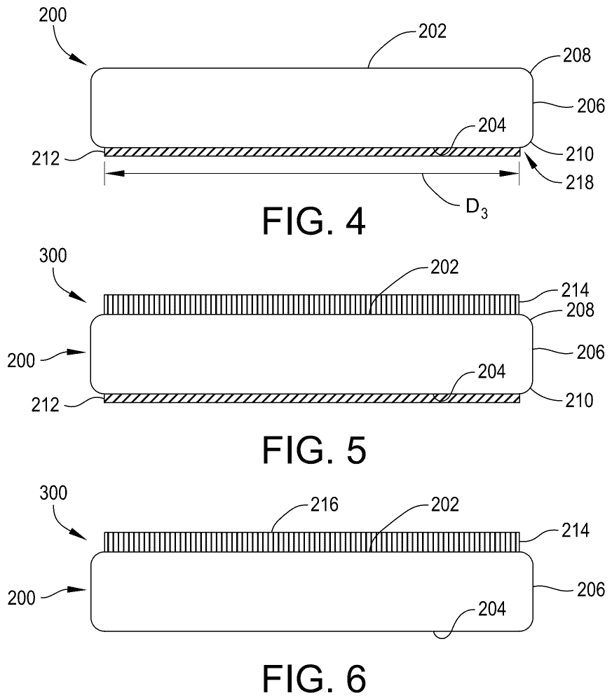

Accordingly, with reference to FIG. 4, the semiconductor oxide layer 212 is removed from regions of the handle substrate 200 other than the back surface 204, including the beveled peripheral edges 208, 210, the circumferential edge 206, and, in some instances, the front surface 202. In embodiments of the present disclosure, removal of the semiconductor oxide layer 212 from these regions is accomplished using an oxide strip or etch technique that selectively removes the semiconductor oxide layer 212 from regions of the substrate 200 other than the back surface 204. Suitable methods and apparatus for accomplishing the selective oxide strip are described, for example, in U.S. Pat. Nos. 11,282,739, issued Mar. 22, 2022; and U.S. Pat. No. 11,798,835, issued Oct. 24, 2023, the disclosures of each of which are incorporated by reference. The oxide etching process is performed to selectively remove the semiconductor oxide layer 212 from the beveled peripheral edges 208, 210, the circumferential edge 206, and, optionally, from the front surface 202, without removing the semiconductor oxide layer 212 from the back surface 204.

The semiconductor oxide layer 212 is suitably stripped or etched from the beveled peripheral edges 208, 210 and the circumferential edge 206 (the “edge regions” of the substrate 200) by edge etching. One example of an edge etch process is a wet edge etch that includes contacting the edge regions with an aqueous acidic etchant, such as an aqueous hydrofluoric acid (HF) solution. An edge etcher apparatus available from Advanced Semiconductor Engineering, Inc. (ASE) is one example of an apparatus that can be used to performing the edge etching process. In some embodiments, the aqueous HF etchant includes another acid, such as acetic acid or hydrochloric acid (HCl), and/or one or more additives such as surfactants, buffers, other oxidizing compounds (e.g., hydrogen peroxide, ozone, and the like), among other additives. In some embodiments, an edge etch process is performed by selectively contacting the edge regions of the substrate 200 with an etchant (e.g., an HF etchant) while rotating the substrate 200 to prevent the etchant from flowing radially inward and etching the semiconductor oxide layer 212 from the back surface 204. The edge etch process may be performed by immersing the edge regions of the substrate 200 in a bath of the etchant and/or spraying or otherwise directing the etchant to the edge regions without contacting the semiconductor oxide layer 212 on the back surface 204 with the etchant. One or more edge etching conditions (e.g., a depth of immersion of the edge regions of the substrate 200 in an etchant bath, a flow rate of the etchant sprayed on the edge regions of the substrate 200, a rotation speed of the substrate 200 during edge etching, and/or a duration of the edge etching process) are controlled to minimize or eliminate a radial gap 218 between the semiconductor oxide layer 212 and the beveled peripheral edge 210. Alternatively stated, the edge etching process is controlled to minimize or eliminate removal of a portion of the semiconductor oxide layer 212 formed on the peripheral region of the back surface 204 adjacent the beveled peripheral edge 210.

In some embodiments, a front side edge process is not performed on the handle substrate 200 between forming the semiconductor oxide layer 212 and forming the charge trapping layer 214. In these embodiments, if the semiconductor oxide layer 212 forms on the front surface 202, it may be removed prior to forming the charge trapping layer 214 using a front surface polishing operation performed on the substrate 200 prior to forming the charge trapping layer 214 on the front surface 202. Alternatively, in some embodiment, if the semiconductor oxide layer 212 forms on the front surface 202, a front side etch process is optionally performed to etch the semiconductor oxide 212 from the front surface 204. The front side etch process may include wet etching the front surface 202 by selectively contacting the front surface 202 of the substrate 200 with the etchant (e.g., an aqueous acidic etchant, such as an aqueous HF solution). In some embodiments, the front side etch process includes selectively spraying the front surface 202 with the etchant. Alternatively, the front side edge process includes partially submerging the front surface 202 in a bath of the etchant. The substrate 200 may be rotated during the front side edge process.

The semiconductor oxide layer 212 is selectively removed (e.g., by edge etching and, optionally, front side etching) from regions of the substrate 200 other than the back surface 204 prior to forming the charge trapping layer 214 such that, when the charge trapping layer is formed on the front surface 202, the semiconductor oxide layer 212 is formed substantially entirely across the back surface 204 between the beveled peripheral edge 210. The other portions of the substrate 200 (i.e., the beveled peripheral edges 208, 210, the circumferential edge 206, and the front surface 202) are devoid of the semiconductor oxide layer 212 prior to forming the charge trapping layer 214. The semiconductor oxide layer 212 being formed “substantially entirely across” the back surface 204 between the beveled peripheral edge 210 means that a diameter D₃ of the semiconductor oxide layer 212 formed on the back surface 204 is substantially equal to (i.e., is at least 98%, or at least 99% of) the diameter D₂ of the back surface 204. In some embodiments, a distance of the radial gap 218 measured between the semiconductor oxide layer 212 formed on the back surface 204 and the beveled peripheral edge 210 is less than 1 mm. Suitably, the radial distance between the semiconductor oxide layer 212 formed on the back surface 204 and the peripheral beveled edge 210 is minimized or eliminated to minimize or eliminate exposed peripheral regions of the back surface 204 of the substrate 200 adjacent the peripheral beveled edge 210 that are not covered by the semiconductor oxide layer 212. This reduces or eliminates the risk of forming the charge trapping layer 214 on the back surface 204 in these regions, which could otherwise contribute to unacceptable flatness characteristics (e.g., SFQR) of the handle substrate 200, and, thus, the handle structure 300.

Still referring to FIG. 4, prior to formation of the charge trapping layer 214, the handle substrate 200 that includes the semiconductor oxide layer 212 formed substantially entirely across the back surface 204 between the beveled peripheral edge 210 is subjected to one or more pre-treatment operations (e.g., clean and/or front surface polish). In some embodiments, the handle substrate 200 is cleaned using an aqueous solution including an oxidizing agent, such as an SC1 and/or an SC2 cleaning solution. One examples of a SC1 solution includes 5 parts deioinized water, 1 part aqueous H₄OH (ammonium hydroxide, 29% by weight of NH₃), and I part of aqueous H₂O₂ (hydrogen peroxide, 30%). One example of a SC2 solution comprises 5 parts deioinized water, 1 part aqueous HCl (hydrochloric acid, 39% by weight), and 1 part of aqueous H₂O₂ (hydrogen peroxide, 30%).

In some embodiments, the front surface 202 of the handle substrate 200 is subjected to a chemical mechanical polishing (“CMP”) operation prior to formation of the charge trapping layer 214 thereon. A suitable CMP operation involves the immersion of the handle substrate 200 in an abrasive slurry and polishing the front surface 202 of the substrate 200 using a polymeric pad, whereby through a combination of chemical and mechanical work the front surface 202 is smoothed to a desired surface roughness. One example of a slurry that is used in the CMP operation contains abrasive particles and a chemical etchant is applied to the polishing pad. As an example, the CMP operation removes less than 1 μm (e.g., about 0.4 μm) of material from the front surface 202 of the substrate 200. In some embodiments, the CMP operation includes removal of fine or “micro” scratches caused by large size colloidal silica, such as Syton® from DuPont Air Products Nanomaterials, LLC, in the polishing slurry to produce a highly reflective, damage-free front surface 202 of the substrate 200. As an example, the CMP operation includes an intermediate polishing operation and a finishing polishing operation, and the intermediate and finishing polishing steps may be performed using the same polishing machine or separate machines. One example of a finish polishing slurry includes an ammonia base and a reduced concentration of colloidal silica. During the finish polishing, the finish polishing slurry is injected between the polishing pad and the front surface 202 of the substrate 200 and the polishing pad works the finish polishing slurry against the front surface 202 to remove any remaining scratches and haze so that the front surface 202 is highly-reflective and damage free.

In some embodiments, prior to formation of the charge trapping layer 214, and optionally after SC1/SC2 clean and polishing the front surface 202, the substrate 200 is subjected to a pre-treatment operation that includes exposing the front surface 202 to an ambient atmosphere comprising reducing agents and/or etching agents. Exposure to the ambient atmosphere comprising reducing agents and/or etching agents may advantageously clean the front surface 202 of the substrate 200, which may include a native oxide front surface layer, and texturizes the front surface 202 for subsequent semiconductor material deposition. The cleaning and etching operation may in some embodiments be performed in the same chamber, e.g., a CVD reaction chamber, in which deposition of the charge trapping layer 214 is performed.

Referring to FIG. 5, after suitable pre-treatment operations have been performed to prepare and treat the front surface 202 of the handle substrate 200, semiconductor material is deposited onto the front surface 202 of the substrate 200 to form the charge trapping layer 214, and thereby form the handle structure 300 that includes the handle substrate 200 and the charge trapping layer 214 formed on the front surface 202 thereof. Semiconductor material suitable for use in forming the charge trapping layer 214 is capable of forming a highly defective layer in the SOI structure 100 between the handle substrate 200 and a dielectric layer subsequently bonded and/or formed on the charge trapping layer 214 (e.g., a dielectric layer 410 of a donor substrate 402 that is bonded to the charge trapping layer 214). Such semiconductor materials include polycrystalline semiconductor materials and amorphous semiconductor materials. Semiconductor materials that may be polycrystalline or amorphous include, for example, silicon (Si), silicon germanium (SiGe), silicon doped with carbon or silicon carbide (SiC), and germanium (Ge). Silicon germanium includes an alloy of silicon germanium in any molar ratio of silicon and germanium.

In some embodiments, the charge trapping layer 214 has a resistivity at least 1000 Ohm-cm, or at least 3000 Ohm-cm, such as between 1000 Ohm-cm to 100,000 Ohm-cm, between 1000 Ohm-cm to 10,000 Ohm-cm, between 2000 Ohm-cm to 10,000 Ohm-cm, between 3000 Ohm-cm to 10,000 Ohm-cm, or between 3000 Ohm cm to 5000 Ohm-cm.

The semiconductor material for deposition onto the front surface 202 of the handle substrate 200 may be deposited by means known in the art to produce the charge trapping layer 214. In some embodiments, the semiconductor material is deposited using chemical vapor deposition (CVD). The CVD deposition technique may be performed at a relatively high temperature (e.g., greater than 700° C., or greater than 800° C.). In some embodiments, the charge trapping layer 214 includes silicon (e.g., polycrystalline silicon or amorphous silicon), and the charge trapping layer 214 is deposited by CVD using a silicon-containing precursor gas (e.g., trichlorosilane). The precursor gases for depositing the semiconductor material may be mixed with a carrier gas such as hydrogen (e.g., trichlorosilane in hydrogen to deposit polycrystalline silicon). The concentration of the precursor gas may be determined based on desired deposition effects (e.g., deposition rate).

In some embodiments, deposition of the semiconductor material to form the charge trapping layer 214 is performed in an atmospheric reactor that may typically be used, for example, for epitaxial deposition on an exposed exterior layer of a semiconductor-on-insulator structure. For example, deposition of the semiconductor material may be performed in an ASM E3000 epi-reactor that includes a gas panel to supply necessary process gases (e.g., H₂, HCl, dichlorosilane, and/or trichlorosilane) at a desired flow rates to a quartz reaction chamber. The quartz reaction chamber may be rectangular in cross section and includes a silicon-carbide coated graphite susceptor that supports the substrate 200 during processing. The susceptor may rotate the substrate 200 and has a recess or pocket that is suitably sized for supporting the substrate 200 (e.g., a 300 mm wafer). The substrate 200 is seated in the recess of the susceptor during processing and is supported on the backside by a ledge in the recess that contacts the substrate 200 in close proximity to (e.g., within a few millimeters from) the circumferential edge 206 of the substrate 200 and at a height that holds the front surface 202 of the substrate 200 slightly above a top surface of the susceptor. The area of the susceptor beneath the substrate 200 and within the supporting ledge of the susceptor may be perforated with holes to allow ventilation of the back surface 204 of the substrate 200 which faces the susceptor. The substrate 200 may be delivered to the reaction chamber by a robot that handles the substrate 200 without substantially introducing contamination or causing damage to the surfaces 202, 204 of the substrate. The reaction chamber is located adjacent to heating elements (e.g., flat lamp banks), which may be nominally parallel with and above and below the substrate 200 and susceptor, which heat the substrate 200 and susceptor to the desired process temperature. The desired gas flow rates, susceptor rotation speed, and temperature typically change at various times throughout the process. Changes in process parameters such as the gas flow rates, rotation speed, temperature, and wafer loading and unloading are controlled by computer automation, based on a predetermined “recipe” that has been developed to produce a substrate 200 with the desired characteristics when processing is complete. Desired characteristics that control process parameters include crystallographic slip in the substrate 200, resistivity, deposited film thickness (e.g., thickness of the charge trapping layer 214), film quality parameters such as resistivity of the charge trapping layer 214, semiconductor material grain size, surface roughness, wafer flatness post-deposition (e.g., site flatness or SFQR), and other characteristics. An exemplary epitaxial reactor suitable for deposition of the charge trapping layer 214 is an epsilon E3000 single-wafer epitaxial reaction manufactured by ASM International. Other reactor chambers include those marketed under the trade name Centura by Applied Materials. Advantageously, performing the charge trapping layer deposition in these reactors may enable several different processes used in semiconductor-on-insulator and RF device fabrication to be run on the same processing tool (e.g., charge trapping layer deposition, post-cleave top semiconductor device layer smoothing by gas phase etching with HCl, top semiconductor device layer thickening by epitaxial deposition, and standard blanket epitaxial layer deposition).

The reaction chamber within which deposition of the charge trapping layer 214 is performed may be at any suitable pressure (e.g., atmospheric) during deposition. For example, deposition may occur at or below atmospheric pressure, such as a pressure between 1 Torr to 760 Torr. As described above, for a CVD process, deposition may occur at a relatively high temperature, such as at least 700° C., or at least 800° C. The deposition time may vary depending on the deposition temperature, concentration and desired thickness of the charge trapping layer 214. In some embodiments, the charge trapping layer 214 is at least 0.1 μm thick, or at least 1 μm thick (e.g., between 0.1 μm to 50 μm thick, such as between 1 μm to 10 μm thick).

The semiconductor material used to form the charge trapping layer 214 may be deposited at any suitable temperature based on the semiconductor material to be deposited, deposition method, and other considerations, and the deposition temperature may be selected to enhance or promote certain properties of the semiconductor layer 110. For example, the deposition temperature of the semiconductor material may be suitable to increase the surface area of the charge trapping layer 214. In some embodiments, the charge trapping layer 214 is deposited at a suitable temperature to decrease the grain size of the deposited semiconductor material. As described above, the charge trapping layer 214 may be deposited using chemical or physical vapor deposition, for example, CVD. In some embodiments, the charge trapping layer 214 includes polycrystalline silicon deposited by CVD, and suitable silicon precursors for CVD include methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), among others. For example, the silicon precursor for depositing the polycrystalline silicon by CVD may be selected from silane, dichlorosilane (SiH₂Cl₂), and trichlorosilane (SiHCl₃). In embodiments in which a silicon precursor is used to deposit polycrystalline silicon by CVD, the polycrystalline silicon may be deposited at a temperature of at least 700° C., or at least 800° C., such as between 800° C. to 1150° C. The temperature may also contribute to high growth rate, thereby contributing to throughput and cost reduction. CVD deposition rates may be at least 0.1 micrometer/minute, such as between about 0.1 micrometer/minute to about 10 micrometers/minute. It will be appreciated that deposition temperatures for certain precursor gases, which depend on whether the semiconductor material includes, for example, polycrystalline or amorphous silicon, SiGe, SiC, or Ge, may be selected based on known suitable temperatures (e.g., according to published methods).

In some embodiments, the handle substrate 200 including the semiconductor oxide layer 212 formed on the back surface 204 and the charge trapping layer 214 formed on the front surface 202 is annealed after deposition of the semiconductor material is complete. Annealing the charge trapping layer 214 contributes to desirable charge trapping layer properties, such as obtaining a clean surface, a high purity film, a high resistivity film, desired nuclei size and uniformity, and reduction of residual film stress. In some embodiments, the charge trapping layer 214 is subjected to a high temperature anneal in order to reduce film stress to a range between 0 MPa to 500 MPa, such as between 0 MPa to 100 MPa. In some embodiments, the handle substrate 200 including the semiconductor oxide layer 212 formed on the back surface 204 and the charge trapping layer 214 formed on the front surface 202 is annealed at a temperature greater than 1000° C., such as between 1000° C. to 1100° C. In some embodiments, the handle substrate 200 including the semiconductor oxide layer 212 formed on the back surface 204 and the charge trapping layer 214 formed on the front surface 202 is annealed for a duration between 1 second to 300 seconds, such as between 5 seconds to 60 seconds. In some embodiments, the ambient atmosphere for the anneal includes hydrogen, hydrogen chloride, chlorine, or any combination of hydrogen, hydrogen chloride, and chlorine. After the appropriate anneal duration, the CVD chamber is cooled to a temperature suitable for removal of the handle structure 300.

In some embodiments, a semiconductor seed layer is deposited onto the front surface 202 of the substrate 200 and annealed prior to depositing the charge trapping layer 214. The semiconductor seed layer is used to promote growth of the subsequent layers of semiconductor material in producing the charge trapping layer 214 and improve charge trapping efficiency of the charge trapping layer 214. The charge trapping layer 214 may thus include the semiconductor seed layer and the subsequently deposited layer(s) of semiconductor material. The semiconductor seed layer may include one or more semiconductor materials such as silicon, SiGe, SiC, and Ge. The semiconductor material used to produce the semiconductor seed layer may be the same material as the subsequently deposited layer(s) of semiconductor material or may be a different semiconductor material. For example, where a polycrystalline semiconductor charge trapping layer 214 is deposited, the semiconductor seed layer may be a polycrystalline semiconductor seed layer. The polycrystalline semiconductor seed layer may include polycrystalline semiconductor material such as, for example, polycrystalline silicon, SiGe, SiC, and/or Ge. The semiconductor seed layer is suitably deposited and annealed in the same reaction chamber as the other layer(s) of the charge trapping layer 214.

The semiconductor seed layer has a thickness less than the thickness of the charge trapping layer 214. In some embodiments, the semiconductor seed layer is deposited to a thickness of less than 20 μm, such as between 50 nanometers (nm) to 20 μm. The thickness of the semiconductor seed layer is set by the size of the semiconductor nuclei. To achieve effective stress release, in some embodiments, the semiconductor seed layer covers the front surface 202 while leaving voids smaller than about 50 nm, which enables the access of hydrogen gas (H₂) to the interface between the semiconductor seed layer and native oxide. Hydrogen gas reduces the native oxide and promotes the diffusion of the atoms at the grain boundaries of the semiconductor seed layer to the substrate 200 and thus releases the film stress. When the semiconductor seed layer is thick enough to completely prevent H₂ access to the native oxide, the subsequent annealing process is not able to release the film stress effectively. On the other hand, when the semiconductor seed layer is not continuous and the opening area between two adjacent nuclei is wider than about 50 nm, large nuclei are formed after the oxide layer is removed during the seed layer annealing process. The large nuclei will grow into large grains (i.e., diameter >1 μm) after the charge trapping layer 214 is deposited, which reduces the trapping efficiency.

The semiconductor seed layer is subjected to a high temperature anneal which is followed by depositing the charge trapping layer 214. Annealing the semiconductor seed layer contributes to desirable charge trapping layer properties, such as obtaining a clean surface, a high purity film, a high resistivity film, desired nuclei size and uniformity, and reduction of compressive film stress. In some embodiments, the semiconductor seed layer is subjected to a high temperature anneal in order to produce tensile stress in the semiconductor seed layer. In some embodiments, the semiconductor seed layer is annealed at a temperature greater than 1000° C., such as between 1000° C. to 1200° C. The semiconductor seed layer may be annealed for a duration between 1 second to 300 seconds, such as between 5 seconds to 60 seconds. The semiconductor seed layer may be annealed in an ambient atmosphere which may contain hydrogen, hydrogen chloride, chlorine, or any combination of hydrogen, hydrogen chloride, and chlorine. The semiconductor seed layer may be performed at reduced pressure or atmospheric pressure, such as between 1 Torr to 760 Torr, The grain size and the stress of the semiconductor seed layer is controlled by the annealing temperature, duration, and gas flow.

In some embodiments, the handle substrate 200 is cooled after annealing the semiconductor seed layer and prior to depositing the charge trapping layer 214. For example, the substrate 200 is cooled to a temperature less than about 1000° C. after annealing the semiconductor seed layer and prior to depositing one or more layers of semiconductor material and annealing the layer(s) to form the charge trapping layer 214.

In some embodiments, the charge trapping layer 214 formed as described above is subsequently planarized or polished to reduce a surface roughness of an exposed surface 216 (FIG. 6) of the charge trapping layer 214 and optimize warp and bow of the handle structure substrate 200 shown in FIGS. 5 and 6 for subsequent operations in producing a semiconductor-on-insulator structure. For example, the charge trapping layer 214 may be subjected to a polishing operation, such as a CMP operation. After formation, the charge trapping layer 214 may have a relatively rough surface and the polishing operation is performed to reduce the surface roughness of the charge trapping layer 214. For example, the deposited charge trapping layer 214 may have a surface roughness as measured by RMS_{2×2μm2} on the order of 50 nm. The charge trapping layer 214 is subjected to a planarization or polishing operation (e.g., CMP) to reduce the surface roughness, preferably to the level of less than 5 Angstroms as measured by RMS_{2×2μm2}, such as between 1 Angstrom to 2 Angstroms, wherein root mean squared—

$${R}_{q} = \sqrt{\frac{1}{N} {\sum }_{i = 1}^{n} {y}_{i}^{2}} ,$$

the roughness profile contains ordered, equally spaced points along the trace, and y; is the vertical distance from the mean line to the data point. At a surface roughness of preferably less than 2 Angstroms, the charge trapping layer 214 is ready for subsequent bonding operations described further below for the preparation of an SOI structure (e.g., the SOI structure 100). In addition to polishing, cleaning of the handle structure 300 having the charge trapping layer 214 is optional. In some embodiments, the handle structure 300 is cleaned, for example, in a standard SC1 and/or SC2 solution.

In has been observed that handle structures including a polished charge trapping layer 214 formed on a front surface thereof are frequently out of specification with respect to the flatness of the handle structure. Flatness is the variation of wafer thickness relative to a reference plane. Flatness can be characterized by global parameters, such as global backside ideal plane/range (GBIR), or local parameters (“site flatness”), such as site backside ideal plane/range (SBIR) or site frontside least squares focal plane range (SFQR). Known metrology tools capable of determining wafer geometry (e.g., KLA-Tencor WaferSight or WaferSight2; Milpitas, Calif.) are suitable for measuring the flatness of a polished wafer (e.g., a handle structure). After polishing the charge trapping layer 214, in conventional handle structures, yield loss as high as 30% has been observed due to handle structures failing to meet site flatness (e.g., SFQR) requirements. In some embodiments, the SFQR requirement for the handle structure is less than or equal to 80 nm, or less than 60 nm, based on a site size of 26 mm×8 mm, as measured by aforementioned metrology tools, which is not achieved at an acceptable yield rate in conventional processes. Efforts to remediate the problem, such as tightening the site flatness specification of the handle substrate and engineering the deposition process used to form the charge trapping layer 214 have been less than optimal and site flatness (e.g., SFQR) yield remains unacceptably low. For example, efforts to reduce the SFQR specification of the handle substrate 200 to below 20 nm and control the deposition process for the charge trapping layer 214 with a target SFQR specification of between 40 nm to 50 nm post deposition have not raised the yield rate of handle structures 300 within SFQR specification to an acceptable level.

Without being bound to a particular theory, it is believed that during formation of the charge trapping layer 214, the semiconductor material that is deposited on the front surface 202 of the substrate 200 has the tendency to leak between the susceptor that supports the substrate 200 in the deposition chamber and the back surface 204 of the substrate 200. This creates the risk of depositing the semiconductor material on the back surface 204 of the substrate 200, contributing to unacceptable site flatness (e.g., SFQR) of the substrate 200. As described above, the substrate 200 is seated in a recess of the susceptor and is supported by a ledge in the recess in close proximity to the circumferential edge 206 of the substrate 200, with the back surface 204 facing an area of the susceptor that is perforated with holes to allow ventilation of the back surface 204. During deposition, the semiconductor material may leak through the ventilation holes and/or between the edge of the substrate 200 and the susceptor ledge, and subsequently deposits on the back surface 204 of the substrate 200. Depending on the area of leakage, the deposition of the semiconductor material is more pronounced near a center of the back surface 204 or near a periphery of the back surface 204, and is typically non-uniform (e.g., deposited at discrete locations that are more populated towards a center of the back surface 204, corresponding to a pattern of the ventilation holes of the susceptor) which further deteriorates site flatness of the substrate 200. Therefore, it is critical to limit or inhibit deposition of the charge trapping layer semiconductor material on the back surface 204 of the substrate 200 to achieve SFQR within specification and at an acceptable yield rate (e.g., greater than 70%, greater than 80%, or greater than 90%).

Accordingly, in the embodiments of the present disclosure, the semiconductor oxide layer 212 is formed on the back surface 204 prior to formation of the charge trapping layer 214 and limits or inhibits deposition of the charge trapping layer semiconductor material on the back surface 204. In some embodiments, as described above, the charge trapping layer 214 is formed by depositing the semiconductor material at a relatively high temperature using CVD (e.g., at least 700° C., or at least 800° C.). The semiconductor oxide layer 212 is particularly effective for preventing backside deposition at the elevated CVD temperatures, where it is more difficult to nucleate semiconductor seeds (e.g., polycrystalline silicon seeds) directly on the semiconductor oxide material. At these temperatures, the semiconductor oxide layer 212 may reduce in thickness or, if the semiconductor oxide layer 212 is not sufficiently thick, may bake off the back surface 204, cither at localized regions in or its entirety, leaving the back surface 204 at least partially exposed and susceptible for deposition of the charge trapping layer semiconductor material. Accordingly, the semiconductor oxide layer 212 has a sufficient thickness to withstand the process conditions during formation of the charge trapping layer 214 without exposing the back surface 204, that is, such that the thickness of any portion of the semiconductor oxide layer 212 is not reduced to a point where a portion the back surface 204 becomes exposed to allow the charge trapping layer semiconductor material to deposit on the back surface 204. As described above, prior to formation of the charge trapping layer 214, the semiconductor oxide layer 212 has a thickness of at least 50 Angstroms, or at least 100 Angstroms, such as between 50 Angstroms to 1000 Angstroms, between 50 Angstroms to 500 Angstroms, between 100 Angstroms to 400 Angstroms, or between 100 Angstroms to 300 Angstroms, or the target thickness of the semiconductor oxide layer 212 prior to formation of the charge trapping layer 214 is 200 Angstroms+/−100 Angstroms.

Referring to FIG. 6, in embodiments of the present disclosure, the semiconductor oxide layer 212 is removed from the handle structure 300 after forming the charge trapping layer 214 and prior to subsequent operations performed on the handle structure 300 (e.g., prior to the polishing operation performed on the charge trapping layer 214). Removal of the semiconductor oxide layer 212 is suitably performed prior to polishing the charge trapping layer 214 to minimize disturbances that the semiconductor oxide layer 212 may have on the polishing process. In some embodiments, the semiconductor oxide layer 212 is removed from the back surface 204 by back side wet etching (e.g., using an HF etchant solution). Suitable apparatus and methods for etching the semiconductor oxide layer 212 include those described above with reference to FIG. 4. The back side etch process may include wet etching the back surface 204 by selectively contacting the back surface 204 of the substrate 200 with the etchant (e.g., an aqueous acidic etchant, such as an aqueous HF solution). In some embodiments, the back side etch process includes selectively spraying the back surface 204 with the etchant. Alternatively, the back side edge process includes partially submerging the back surface 204 in a bath of the etchant. The substrate 200 may be rotated during the back side edge process. The thickness of the semiconductor oxide layer 212 is within the above-stated ranges (e.g., between 50 Angstroms to 1000 Angstroms) to allow efficient removal of the semiconductor oxide layer 212 without excessive effort while also being sufficiently thick to limit or inhibit deposition of the charge trapping layer semiconductor material on the back surface 204.

Alternatively, in some embodiments, the semiconductor oxide layer 212 is not removed and may remain on the back surface 204 of the handle structure 300 during subsequent operations, including operations used to prepare the SOI structure 100.

In the embodiments of the present disclosure, following the polishing operation performed on the charge trapping layer 214 and, optionally, removal of the semiconductor oxide layer 212, the handle structure 300 has an acceptable SFQR. For example, the handle structure 300 prepared according to methods of the present disclosure has an SFQR of less than or equal to 80 nm, or less than 60 nm, based on a site size of 26 mm×8 mm, as measured by aforementioned metrology tools (e.g., KLA-Tencor WaferSight or WaferSight2). Furthermore, the use of the semiconductor oxide layer 212 provides an effective and cost-efficient solution to the flatness problem commonly associated with handle structures including a charge trapping layer 214 formed on a front surface thereof, and enables the handle structure 300 having the acceptable SFQR to be repeatedly and consistently prepare to thereby increase the yield rate of acceptable SFQR structures 300. For example, the methods of the present disclosure enable preparing handle structures 300 having acceptable SFQR (e.g., less than 80 nm, or less than 60 nm) at a yield of at least 70%, at least 80%, or at least 90%.

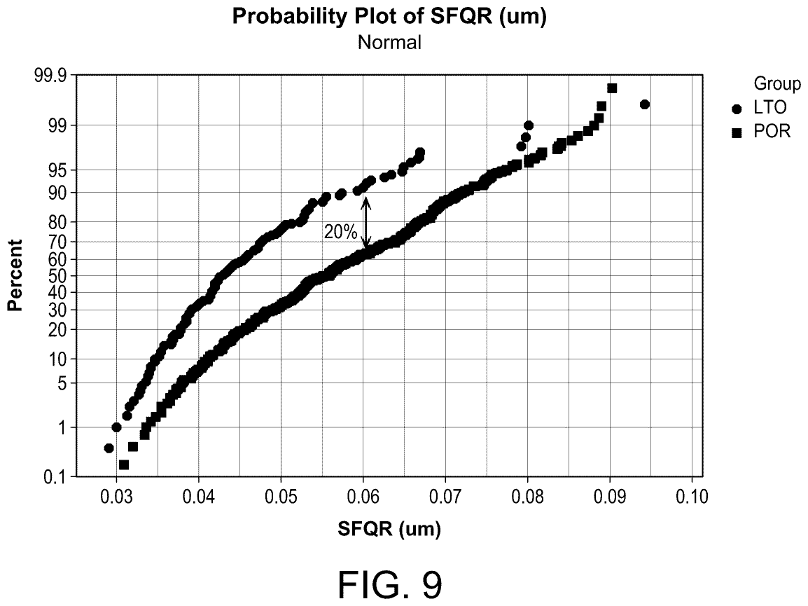

FIG. 9 is a probability plot of SFQR (measured in μm) and compares the SFQR of handle structures 300 prepared in accordance with embodiments of the present disclosure (group labeled “LTO”) to the SFQR of handle structures in which a charge trapping layer is deposited without using a semiconductor oxide layer on the back surface 204 of the handle substrate 200 (group labeled “POR”). The comparison was conducted using 375 POR handle structures and 166 LTO handle structures. The same process conditions for depositing the charge trapping layer (a polycrystalline silicon charge trapping layer) was used for each of POR and the LTO handle structures to create similar thickness profile. Silicon oxide was used as the semiconductor oxide layer in the LTO handle structures. Each of the POR and LTO handle structures were subjected to CMP to polish the front surface of the charge trapping layer. As shown in FIG. 9, after CMP, the LTO handle structures have better SFQR compared to the POR group. In particular, the SFQR of the LTO group showed an improvement of about 10 nm on the median value and about a 20% projected final yield improvement.

### Preparation of Semiconductor-on-Insulator Structures

Referring to FIGS. 1, 7, and 8, embodiments of the present disclosure also relate to preparing multilayer or SOI structures (e.g., the SOI structure of FIG. 1) using the handle structure 300 prepared in accordance with the methods described above with reference to FIGS. 2-6. Such methods of preparing the SOI structure 100 using the handle structure 300 will now be described.

In general, the SOI structure 100 is prepared by bonding the handle structure 300 to a donor structure 400 that includes a single crystal semiconductor donor substrate 402. In some embodiments, the donor substrate 402 is similar in construction to the handle substrate 200, and includes a front surface 404, a back surface 406, and a circumferential edge 408 joining the front surface 404 and the back surface 406. The front surface 404 of the donor substrate 402 includes a dielectric layer 410, e.g., a silicon dioxide layer, which forms the buried oxide (BOX) layer (i.e., the dielectric layer 106) in the final structure 100. In some embodiments, a dielectric layer is additionally or alternatively formed on the surface 216 of the charge trapping layer 214 and forms, in part or in whole, the dielectric layer 106 in the final structure 100. The back surface 406 of the donor substrate 402 becomes an exterior surface of the bonded structure 500 (FIG. 8) or a semiconductor-on-insulator structure 100 (FIG. 1). As described above for the substrate 200, the donor substrate 402 also includes a central plane between the front surface 404 and the back surface 406, and an imaginary central axis substantially perpendicular to the central plane. Upon completion of bonding and wafer thinning operations, described in further detail below, the donor substrate 402 forms a semiconductor device layer (e.g., the device layer 108) of the SOI structure 100. The handle structure 300 provides the handle substrate 102 (i.e., the handle substrate 200) and the charge trapping layer 104 (i.e., the charge trapping layer 214) in the SOI structure 100. The dielectric layer 106 is formed form the dielectric layer 410 on the front surface 404 of the donor substrate 402 in some embodiments, but may be formed additionally or alternatively from a dielectric layer formed on the charge trapping layer 214 of the handle structure 300.

Like the substrate 200, the donor substrate 402 may be a single crystal semiconductor wafer. In some embodiments, the donor substrate 402 includes a semiconductor material selected from the group consisting of silicon, silicon carbide, silicon germanium, gallium arsenide, gallium nitride, indium phosphide, indium gallium arsenide, germanium, and combinations thereof. Depending upon the desired properties of the final integrated circuit device, the single crystal semiconductor (e.g., silicon) donor substrate 402 may include a dopant selected from the group consisting of boron, arsenic, and phosphorus. The resistivity of the single crystal semiconductor (e.g., silicon) donor substrate 402 may range from 0.01 Ohm-cm to 500 Ohm-cm. The single crystal semiconductor donor substrate 402 may be subjected to standard process steps including oxidation, implant, and post implant cleaning. Accordingly, a semiconductor donor substrate 402, such as a single crystal semiconductor wafer of a material that is conventionally used in preparation of multilayer semiconductor structures, e.g., a single crystal silicon donor wafer, that has been etched and polished and optionally oxidized, is subjected to ion implantation to form a damage layer or cleave plane 412 in the donor substrate 402.

Suitable dielectric layers 410 of the donor structure 400 include a material selected from among silicon dioxide, silicon nitride, silicon oxynitride, hafnium oxide, titanium oxide, zirconium oxide, lanthanum oxide, barium oxide, aluminum oxide, aluminum nitride, and any combination thereof. In some embodiments, the dielectric layer 410 includes an oxide layer having a thickness of at least about 10 nm thick, such as between about 10 nm and about 10,000 nm.

In some embodiments, the front surface 404 of the donor substrate 400 (e.g., a single crystal silicon donor substrate) is thermally oxidized to prepare the dielectric layer 410 (e.g., a semiconductor oxide film, such as a silicon dioxide film). Alternatively, the dielectric layer 410 (e.g., a silicon dioxide film) is grown by CVD oxide deposition on the front surface 404. Suitable oxidizing operations performed on the front surface 404 of the donor substrate 402 include those described above for forming the semiconductor oxide layer 212. In some embodiments, the front surface 404 of the single crystal semiconductor donor substrate 402 is thermally oxidized in a furnace such as an ASM A400 or an ASM A412 in the same manner described above.

The semiconductor device layer 108 in the SOI structure 100 shown in FIG. 1 is derived from the single crystal semiconductor donor substrate 402. In particular, a portion of the donor substrate 402 is removed from the bonded structure 500 to thereby transfer the device layer 108 and the dielectric layer 106/410 onto the handle structure 300 and form the SOI structure 100. The device layer 108 and dielectric layer 106/410 may be transferred onto the handle structure 300 by wafer thinning techniques such as etching the donor substrate 402 or by cleaving the donor substrate 402 at the cleave plane 412.

In some embodiments, the cleave plane 412 is formed in the donor substrate 402 by ion implantation techniques. Ion implantation is suitably carried out in a commercially available instrument, such as an Applied Materials Quantum H. Implanted ions include He, H, H₂, or combinations thereof. Ion implantation is carried out as a density and duration sufficient to form the cleave plane 412 in the donor substrate 402. Implant density may range from 10¹² ions/cm² to 10¹⁷ ions/cm², such as from 10¹⁴ ions/cm² to 10¹⁷ ions/cm². Implant energies may range from 1 keV to 3,000 keV, such as from 5 keV to 3,000 keV. The depth of implantation determines, at least in part, the thickness of the device layer 108 in the final SOI structure 100 (shown in FIG. 1). In some embodiments, ion implantation is performed after formation of the dielectric layer 410 on the front surface 404 of the donor substrate 402. In some embodiments, the donor substrate 402 is subjected to a cleaning operation after the implant. A suitable clean includes a Piranha clean followed by a deionized water rinse and/or cleaning using a SC1 and/or SC2 solution.

In some embodiments, the donor substrate 402 having been subjected to helium ion and/or hydrogen ion implant is annealed at a temperature sufficient to form a thermally activated cleave plane 412 in the donor substrate 400. An example of a suitable tool includes a Box furnace, such as a Blue M model. In some embodiments, the ion implanted donor substrate 402 is annealed at a temperature of from 200° C. to 350° C. Thermal annealing may occur for a duration of from 2 hours to 10 hours. Thermal annealing within these temperatures ranges is sufficient to form a thermally activated cleave plane 412. After the thermal anneal to activate the cleave plane 412, the front surface 404, which may optionally include the dielectric layer 410, and optionally the back surface 406, of the donor substrate 402 may be cleaned using cleaning operations described above.

In some embodiments, the ion-implanted and optionally cleaned and optionally annealed donor structure 400 is subjected to oxygen plasma and/or nitrogen plasma surface activation. In some embodiments, the oxygen plasma surface activation tool is a commercially available tool, such as those available from EV Group, such as EVG®810LT Low Temp Plasma Activation System. The ion-implanted and optionally cleaned donor structure 400 is loaded into the chamber. The chamber is evacuated and backfilled with O₂ to a pressure less than atmospheric to thereby create the plasma. The donor structure 400 is exposed to this plasma for the desired time, which may range from 1 second to 120 seconds. Oxygen plasma surface oxidation is performed in order to render an exposed surface 414 of the dielectric layer 410, or the front surface 404 of the donor substrate 402 if the dielectric layer 410 is not included in the donor structure 400, hydrophilic and amenable to bonding to the handle structure 300 prepared according to the method described above. In some embodiments, the surface 216 of the charge trapping layer 214 is also subjected to plasma surface activation prior to bonding.

Referring to FIGS. 7 and 8, the plasma activated front surface layer of the donor structure 400 (e.g., the hydrophilic exposed surface 414 of the dielectric layer 410) and the exposed, and optionally plasma activated, surface 216 of the charge trapping layer 214 of the handle structure 300 are next brought into intimate contact to thereby form the bonded structure 500. In the illustrated embodiment, the bonded structure 500 includes the dielectric layer 410, e.g., a buried oxide layer, of the donor structure 400 in interfacial contact with the charge trapping layer 214 of the handle structure 300.

Since the mechanical bond between the handle structure 300 and the donor structure 400 is relatively weak, the bonded structure 500 is further annealed to solidify the bond. In some embodiments, the bonded structure 500 is annealed at a temperature sufficient to form a thermally activated cleave plane 412 in the single crystal semiconductor donor substrate 402. An example of a suitable tool might be a Box furnace, such as a Blue M model. In some embodiments, the bonded structure 400 is annealed at a temperature of from 200° C. to 350° C. Thermal annealing may occur for a duration of from 0.5 hours to 10 hours. Thermal annealing within these temperature ranges is sufficient to form a thermally activated cleave plane 412. After the thermal anneal to strengthen the bond, the bonded structure 500 may be cleaved at the cleave plane 412 to produce the final SOI structure 100 (shown in FIG. 1) that includes the handle substrate 102/200, the charge trapping layer 104/214, the dielectric layer 106/410, and the device layer 108. Alternatively, a portion of the donor substrate 402 may be removed using another suitable layer transfer or wafer thinning technique to form the final SOI structure 100, such as grinding or back-side etching.

Cleaving the bonded structure 500 is performed according to techniques known in the art. In some embodiments, the bonded structure 500 may be placed in a conventional cleave station affixed to stationary suction cups on one side (e.g., on one of the back surfaces 204, 406) and affixed by additional suction cups on a hinged arm on the other side (e.g., on another one of the back surfaces 204, 406). A crack is initiated near the suction cup attachment and the movable arm pivots about the hinge cleaving the donor substrate 402 apart at the cleave plane 412. Cleaving removes a portion of the semiconductor donor substrate 402, thereby transferring the device layer 108 (e.g., a silicon device layer) on the SOI structure 100.

After transfer of the device layer 108 (e.g., by cleave), the SOI structure 100 may be subjected to post-layer transfer processing to smooth the outer surface 100 of the device layer 108. For example, after layer transfer, the SOI structure 100 may be subjected to a high temperature anneal, which may also strengthen the bonds between adjacent layers of the SOI structure 100. The high temperature anneal may be performed on multiple SOI structures 100 in a batch furnace to reduce costs, but may be performed on an individual SOI structure 100 in a single wafer processing chamber. An example of a suitable tool for the high temperature anneal is a vertical furnace, such as an ASM A400 or an ASM A412. The high temperature anneal is suitably performed at a temperature and for a duration sufficient to smooth a surface of the device layer 108 and/or strengthen the bonds between adjacent layers in the SOI structure 100. In some embodiments, the SOI structure 100 is annealed at a temperature of greater than or equal to 950° C., such as between 1000° C. to 1200° C., and for a duration of between 15 minutes to 10 hours. The high temperature anneal of the SOI structure 100 may, in some embodiments, be performed in the presence of an anneal atmosphere that includes at least one of an inert gas (e.g., argon gas), hydrogen (H₂) gas, and helium gas, or a combination of two or more of these gases. For example, the high temperature anneal may be performed at a temperature of between 1000° C. to 1200° C., for a duration of between 2 hours to 4 hours, in the presence of argon gas. The high temperature anneal may additionally and/or alternatively be performed in an “active” gas environment, for example, in the presence of nitrogen (N₂) gas, oxygen (O₂) gas, or a combination of N₂ and O₂ gas. A high temperature anneal in an active gas environment may be performed to strengthen the bonds between adjacent layers of the SOI structure 100, but typically will not smooth surfaces of the SOI structure 100 (e.g., the outer surface 110 of the device layer 108).

In some embodiments, the SOI structure 100 may be subjected to post-layer transfer smoothing operations in addition to or in the alternative to the high temperature anneal. For example, a polishing operation, such as CMP, may be performed on the SOI structure 100 to planarize one or both of the exposed surfaces of the SOI structure (e.g., the outer surface 110 of the transferred device layer 108). The polishing operation may be performed in addition to (e.g., before and/or after) or in the alternative to the high temperature thermal anneal. For example, a CMP operation may be performed on the transferred device layer 108, followed by the high temperature thermal anneal performed on the SOI structure 100. Additionally or alternatively, the SOI structure 100 is subjected to a non-contact smoothing process, also referred to as epitaxial smoothing or “epi-smoothing,” after the high temperature anneal and/or the polishing operation. The epi-smoothing process may further reduce the roughness of the outer surface 110 of the device layer 108 on the SOI structure 100 and/or remove any implant damage of the device layer 108 that was not compensated for by any previous smoothing processes (e.g., in the high temperature thermal anneal and/or the polishing operation). Example epi-smoothing processes are described, for example, in U.S. Pat. No. 9,202,711, issued Dec. 1, 2015, the disclosure of which is hereby incorporated by reference herein in its entirety. The epi-smoothing process is typically performed in a suitable reactor (e.g., an epitaxial deposition reactor) that is operable to heat the SOI structure 100 in a reaction chamber and introduce etchant gases into the reaction chamber that perform work on (e.g., etch) the transferred device layer 108 to further smooth the outer surface 110. For example, the epi-smoothing process may include positioning the SOI structure 100 in an epi-reactor chamber, heating the chamber to a temperature between 900° C. and 1100° C., introducing gaseous etchant (e.g., hydrogen chloride, HCl, or chlorine and hydrogen gas, H₂) into the chamber, and maintaining temperature and flow of the gaseous etchant for a suitable duration to achieve a targeted surface roughness of the transferred device layer 108.

Following layer transfer of the device layer 108 and any additional post-layer transfer smoothing operations performed on the SOI structure 100, the device layer 108 has a suitable thickness for device fabrication. The SOI structure 100 may subsequently be subjected to further processing based on an intended application or use of the SOI structure. For example, an epitaxial layer may be deposited on the outer surface 110 of the transferred device layer 108. An epitaxial layer deposited on the device layer 108 may include substantially the same electrical characteristics as the underlying device layer. Alternatively, the epitaxial layer deposited on the device layer 108 may include different electrical characteristics as the underlying device layer. An epitaxial layer may comprise a material selected from the group consisting of silicon, silicon carbide, silicon germanium, gallium arsenide, gallium nitride, indium phosphide, indium gallium arsenide, germanium, and combinations thereof. In embodiments where epi-smoothing is performed on the SOI structure 100, the SOI structure may remain in the reactor and be subjected to an epi-deposition process in the same reactor, or the epitaxial layer may be deposited on the device layer 108 in a separate reactor. Depending upon the desired properties of the final device, the epitaxial layer may comprise a dopant, such as one or more p-type dopants (e.g., boron, gallium, aluminum, and/or indium) and/or one or more n-type dopants (e.g., phosphorus, antimony, and/or arsenic). The final SOI structure 100 may additionally and/or alternatively be subjected to end of line metrology inspections and cleaned a final time using typical SC1-SC2 process. Oxidation may further be performed on one or more exposed surfaces of the SOI structure 100 for reducing bow or warp of the structure 100.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” “front,” back,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method of preparing a multilayer structure, the method comprising:
forming a charge trapping layer on a front surface of a single crystal semiconductor handle substrate by depositing a semiconductor material on the front surface, wherein the single crystal semiconductor handle substrate includes the front surface, a back surface, a circumferential edge joining the front and back surfaces, wherein a semiconductor oxide layer is formed on the back surface and has a thickness of between 50 Angstroms to 1000 Angstroms, and wherein, during deposition of the semiconductor material on the front surface, the semiconductor oxide layer limits deposition of the semiconductor material on the back surface;
bonding the charge trapping layer to a donor structure including a single crystal semiconductor donor substrate to thereby form a bonded structure; and
removing a portion of the single crystal semiconductor donor substrate from the bonded structure to thereby transfer a single crystal semiconductor device layer onto the charge trapping layer and form the multilayer structure.

2. The method of claim 1, wherein the thickness of the semiconductor oxide layer is between 50 Angstroms to 500 Angstroms.

3. The method of claim 1, further comprising polishing the charge trapping layer formed on the front surface.

4. The method of claim 3, wherein polishing the charge trapping layer includes chemical mechanical polishing.

5. The method of claim 3, further comprising removing the semiconductor oxide layer from the back surface after forming the charge trapping layer on the front surface and prior to polishing the charge trapping layer.

6. The method of claim 3, wherein, after polishing the charge trapping layer, the single crystal semiconductor handle substrate with the charge trapping layer formed thereon has a site frontside least squares focal plane range (SFQR) of less than or equal to 80 nm.

7. The method of claim 1, further comprising removing the semiconductor oxide layer from the back surface after forming the charge trapping layer on the front surface.

8. The method of claim 1, wherein the semiconductor oxide layer is formed on the back surface using chemical vapor deposition.

9. The method of claim 8, wherein the semiconductor oxide layer is formed on the back surface using plasma enhanced chemical vapor deposition or atmosphere pressure chemical vapor deposition at a temperature of less than 450° C.

10. The method of claim 8, wherein the semiconductor oxide layer is deposited on the back surface in an atmosphere containing an oxygen-containing precursor and a silicon-containing precursor.

11. The method of claim 10, wherein the oxygen-containing precursor includes nitrous oxide (N₂O) and the silicon-containing precursor includes silane.

12. The method of claim 1, wherein the semiconductor oxide layer includes silicon oxide.

13. The method of claim 1, wherein the single crystal semiconductor handle substrate includes a beveled peripheral edge extending between the back surface and the circumferential edge, wherein the beveled peripheral edge is devoid of the semiconductor oxide layer and the semiconductor oxide layer is formed substantially entirely across the back surface between the beveled peripheral edge.

14. The method of claim 13, wherein the semiconductor oxide layer is within a radial distance of 1 mm from the beveled peripheral edge.

15. The method of claim 1, wherein the front surface is polished prior to forming the charge trapping layer.

16. The method of claim 1, wherein the single crystal semiconductor handle substrate includes single crystal silicon material.

17. The method of claim 16, wherein the single crystal semiconductor handle substrate has an interstitial oxygen concentration of less than 9 nppma (4.5×10¹⁷ atoms/cm³), less than 6 nppma (3×10¹⁷ atoms/cm³), or less than 5 nppma (2.5×10¹⁷ atoms/cm³).

18. The method of claim 1, wherein the semiconductor material deposited on the front surface includes polycrystalline semiconductor material or amorphous semiconductor material.

19. The method of claim 18, wherein the semiconductor material includes polycrystalline silicon material or amorphous silicon material.

20. The method of claim 1, wherein depositing the semiconductor material on the front surface comprises depositing the semiconductor material at a temperature of at least 700° C.

21. A method of preparing a handle structure for use in a semiconductor-on-insulator structure, the method comprising:
forming a charge trapping layer on a front surface of a single crystal semiconductor handle substrate by depositing a semiconductor material on the front surface, wherein the single crystal semiconductor handle substrate includes the front surface, a back surface, a circumferential edge joining the front and back surfaces, and a semiconductor oxide layer formed on the back surface, wherein, during deposition of the semiconductor material on the front surface, the semiconductor oxide layer limits deposition of the semiconductor material on the back surface, and wherein the semiconductor oxide layer has a sufficient thickness to withstand the deposition of the semiconductor material without exposing the back surface;
removing the semiconductor oxide layer from the back surface after forming the charge trapping layer on the front surface; and
polishing the charge trapping layer after removing the semiconductor oxide layer to thereby prepare the handle structure.

22. The method of claim 21, wherein the thickness of the semiconductor oxide layer is between 50 Angstroms to 1000 Angstroms.

23. The method of claim 21, wherein semiconductor oxide layer is removed by wet etching.

24. The method of claim 21, wherein polishing the charge trapping layer includes chemical mechanical polishing.

25. The method of claim 21, wherein the handle structure has a site frontside least squares focal plane range (SFQR) of less than or equal to 80 nm.

26. The method of claim 21, wherein the semiconductor oxide layer is formed on the back surface using chemical vapor deposition.

27. The method of claim 26, wherein the semiconductor oxide layer is formed on the back surface using plasma enhanced chemical vapor deposition or atmosphere pressure chemical vapor deposition at a temperature of less than 450° C.

28. The method of claim 26, wherein the semiconductor oxide layer is deposited on the back surface in an atmosphere containing an oxygen-containing precursor and a silicon-containing precursor.

29. The method of claim 28, wherein the oxygen-containing precursor includes nitrous oxide (N₂O) and the silicon-containing precursor includes silane.

30. The method of claim 21, wherein the semiconductor oxide layer includes silicon oxide.

31. The method of claim 21, wherein the single crystal semiconductor handle substrate includes a beveled peripheral edge extending between the back surface and the circumferential edge, wherein the beveled peripheral edge is devoid of the semiconductor oxide layer and the semiconductor oxide layer is formed substantially entirely across the back surface between the beveled peripheral edge.

32. The method of claim 31, wherein the semiconductor oxide layer is within a radial distance of 1 mm from the beveled peripheral edge.

33. The method of claim 21, wherein the front surface is polished prior to forming the charge trapping layer.

34. A method of preparing a handle structure for use in a semiconductor-on-insulator structure, the method comprising:
forming a semiconductor oxide layer on a back surface of a single crystal semiconductor handle substrate by depositing a semiconductor oxide material on the back surface, wherein the single crystal semiconductor handle substrate includes a front surface, the back surface, a circumferential edge joining the front and back surfaces, and a beveled peripheral edge extending between the circumferential edge and the back surface, wherein the semiconductor oxide material is also deposited on the beveled peripheral edge;
removing the semiconductor oxide material from the beveled peripheral edge such that the semiconductor oxide layer is formed substantially entirely across the back surface between the beveled peripheral edge; and
forming a charge trapping layer on the front surface by depositing a semiconductor material on the front surface to thereby form the handle structure, wherein, during deposition of the semiconductor material on the front surface, the semiconductor oxide layer limits deposition of the semiconductor material on the back surface, and wherein the semiconductor oxide layer has a sufficient thickness to withstand the deposition of the semiconductor material without exposing the back surface.

35. The method of claim 34, wherein the semiconductor oxide layer is within a radial distance of 1 mm from the beveled peripheral edge after removing the semiconductor oxide material from the beveled peripheral edge.

36. The method of claim 34, wherein the thickness of the semiconductor oxide layer is between 50 Angstroms to 1000 Angstroms.

37. The method of claim 34, further comprising polishing the charge trapping layer formed on the front surface.

38. The method of claim 37, wherein polishing the charge trapping layer includes chemical mechanical polishing.

39. The method of claim 37, further comprising removing the semiconductor oxide layer from the back surface after forming the charge trapping layer on the front surface and prior to polishing the charge trapping layer.

40. The method of claim 37, wherein, after polishing the charge trapping layer, the handle structure has a site frontside least squares focal plane range (SFQR) of less than or equal to 80 nm.

41. The method of claim 37, further comprising removing the semiconductor oxide layer from the back surface after forming the charge trapping layer on the front surface.

42. The method of claim 34, wherein forming the semiconductor oxide layer comprises depositing the semiconductor oxide material on the back surface using chemical vapor deposition.

43. The method of claim 42, wherein forming the semiconductor oxide layer comprises depositing the semiconductor oxide material on the back surface using plasma enhanced chemical vapor deposition or atmosphere pressure chemical vapor deposition at a temperature of less than 450° C.

44. The method of claim 34, wherein forming the semiconductor oxide layer comprises depositing the semiconductor oxide material on the back surface in an atmosphere containing an oxygen-containing precursor and a silicon-containing precursor.

45. The method of claim 44, wherein the oxygen-containing precursor includes nitrous oxide (N₂O) and the silicon-containing precursor includes silane.

46. The method of claim 34, wherein the semiconductor oxide material includes silicon oxide.

47. The method of claim 34, further comprising polishing the front surface after forming the semiconductor oxide layer and prior to forming the charge trapping layer.

48. The method of claim 34, further comprising polishing the front surface and the back surface prior to forming the semiconductor oxide layer.

49. The method of claim 34, further comprising polishing the beveled peripheral edge prior to forming the semiconductor oxide layer.
